(19) United States
(12) Patent Application Publication
(10) Pub. No.: US 2026/0287336 A1
(43) Pub. Date: Sep. 24, 2026

(54) SHAPE INSPECTION METHOD FOR INSPECTION-TARGET OBJECT

(71) Applicant: Mitsubishi Electric Corporation, Tokyo (JP)

(72) Inventor: Jun OGATA, Tokyo (JP)

(73) Assignee: Mitsubishi Electric Corporation, Tokyo (JP)

(21) Appl. No.: 19/475,405

(22) PCT Filed: May 19, 2023
(86) PCT No.: PCT/JP2023/018731

§ 371 Date: Oct. 14, 2025

(51) Int. Cl. G01B 11/25; G01N 21/88

(52) U.S. Cl. CPC G01B 11/254; G01N 21/8806; G01N 2021/8835; G01N 2021/8845

(57) ABSTRACT

A shape inspection method for an inspection-target object, wherein with respect to the inspection-target object, while a position of the illumination device is changed, for each changed position, from a plane position of the inspection-target object when the inspection-target object is projected on a plane perpendicular to an optical axis of the camera, an angle shape of the inspection-target object calculated from an angular position of the illumination device when regular reflection light from the inspection-target object enters the camera, and a top height of the inspection-target object calculated from an image taken at an in-focus position when the camera is moved in an optical-axis direction of the camera relative to the inspection-target object, the three-dimensional shape of the inspection-target object is calculated, and a shape of the inspection-target object is determined.

### TECHNICAL FIELD

The present disclosure relates to a shape inspection apparatus and a shape inspection method for an inspection-target object.

### BACKGROUND ART

A conventional shape inspection apparatus for a bonding wire which is an inspection-target object performs inspection of a wire shape by taking an image of a wire from above by a 2D camera and then comparing the image with proper product data. However, with this method, information on the depth-direction shape of the wire cannot be obtained, and therefore it is impossible to perform determination for a loop shape, contact between crossing wires, or contact between a wire and a structure.

In this regard, a device or a sensor capable of measuring a three-dimensional shape is also available. As a measurement method for a three-dimensional shape, for example, there is a method using a stereo camera or a laser beam, but such devices are all expensive and it takes time to perform measurement.

In Patent Document 1, laser slit light rays having different wavelengths are emitted to a bonding wire, and a binarized pattern of each ray of reflection light is compared with proper product data, to perform quality determination for a three-dimensional shape of a bonding wire.

### CITATION LIST

### Patent Document

Patent Document 1: Japanese Laid-Open Patent Publication No. 7-037955
Patent Document 2: Japanese Laid-Open Patent Publication No. 4-250347

### SUMMARY OF THE INVENTION

### Problem to be Solved by the Invention

Since a bonding wire has a three-dimensional structure, merely taking an image in one direction by a 2D (plane) camera cannot provide information in a depth direction perpendicular to the plane. If images of the wire are taken in a plurality of directions by the 2D camera, the three-dimensional shape can be measured, but in most cases, such bonding wires are mounted in a large amount to one product, and therefore it takes extremely long time to take images of all wires in a plurality of directions. In addition, there is a case where an image of a target wire cannot be taken because the target wire is obstructed by another wire or a structure.

In Patent Document 1, laser slit light rays are emitted to a bonding wire, and a binarized pattern of each of reflection light rays is compared with proper product data, whereby proper product determination for the three-dimensional shape of the bonding wire is performed. However, the absolute value of the wire position is not measured. Therefore, it is impossible to perform determination for contact between crossing wires or contact between a wire and a structure.

The present disclosure has been made to solve the above problem, and an object of the present disclosure is to provide a wire shape inspection apparatus which measures the three-dimensional shape of a bonding wire which is an inspection-target object by a camera capable of recognizing a two-dimensional shape, and can perform inspection regarding defects of a large number of wires used in products, e.g., bending of a wire, contact between crossing wires, or contact between a wire and a structure, at high speed and using an inexpensive apparatus configuration, before shipping of the products.

### Means to Solve the Problem

A bonding wire shape inspection apparatus according to the present disclosure includes: a camera which is provided movably relative to the inspection-target object and takes an image of the inspection-target object; an adjustment mechanism for adjusting a distance between the camera and the inspection-target object; an illumination device which has a light source for emitting light to the inspection-target object and is capable of changing a position of the light source; a controller which controls operation of the adjustment mechanism and controls position change operation of the light source of the illumination device, light-up operation thereof, change operation of a spectrum distribution thereof, and operation for the camera to take an image of the inspection-target object; and a computer which outputs an operation command for commanding operation of changing positions of the camera and the light source relative to the inspection-target object, light-up operation of the light source, operation of changing the spectrum distribution of the light source, and operation for the camera to take an image of the inspection-target object. While the position of the camera is moved and an irradiation position of light from the light source to the inspection-target object is changed, an image of the inspection-target object is taken, and on the basis of the taken image, a shape of the inspection-target object is estimated and compared with a shape of an inspection-target object as a reference measured in advance, by the computer, to determine a three-dimensional shape of the inspection-target object.

### Effect of the Invention

With the bonding wire shape inspection apparatus according to the present disclosure, it becomes possible to provide a wire shape inspection apparatus which measures the three-dimensional shape of a bonding wire which is an inspection-target object by a camera capable of recognizing a two-dimensional shape, and can perform inspection regarding defects of a large number of wires used in products, e.g., bending of a wire, contact between crossing wires, or contact between a wire and a structure, at high speed and using an inexpensive apparatus configuration, before shipping of the products.

### BRIEF DESCRIPTION OF THE DRAWINGS

FIG. 1 shows an example of the configuration of a shape inspection apparatus for an inspection-target object according to embodiment 1.

FIG. 2 shows a state of reflection light reflected from the inspection-target object.

FIG. 3A illustrates paths of regular reflection light when illumination light is emitted to an inspection-target object having a normal shape.

FIG. 3B illustrates paths of regular reflection light when illumination light is emitted to an inspection-target object having a defective shape.

FIG. 4 is a flowchart illustrating the outline of quality determination for the shape of an inspection-target object.

FIG. 5 illustrates quality determination for the shape of an inspection-target object, using a specific example.

FIG. 6 is a flowchart illustrating a plane shape measurement method for an inspection-target object.

FIG. 7 illustrates the details of the plane shape measurement method for an inspection-target object.

FIG. 8 is a flowchart illustrating an angle shape measurement method for an inspection-target object.

FIG. 9 illustrates the angle shape of an inspection-target object measured through angle shape measurement for the inspection-target object.

FIG. 10 illustrates a plane shape and an angle shape in shape measurement for an inspection-target object, using measurement points.

FIG. 11 is a flowchart illustrating a measurement method for the height of the top of an inspection-target object.

FIG. 12 illustrates the height of the top of an inspection-target object upon measurement.

FIG. 13 illustrates a shape inspection method for an inspection-target object according to embodiment 2.

FIG. 14 shows an example of a shape inspection apparatus for an inspection-target object according to embodiment 3.

FIG. 15A shows placement of an inspection-target object and a shape inspection apparatus in a case of inspecting the inspection-target object having a height difference by the shape inspection apparatus for the inspection-target object according to embodiment 1.

FIG. 15B shows placement of an inspection-target object and a shape inspection apparatus in a case of inspecting the inspection-target object having a height difference by the shape inspection apparatus for the inspection-target object according to embodiment 4.

FIG. 16 illustrates hardware implementing a controller and a computer used in the shape inspection apparatus for the inspection-target object according to any of embodiments 1 to 4.

### DESCRIPTION OF EMBODIMENTS

### Embodiment 1

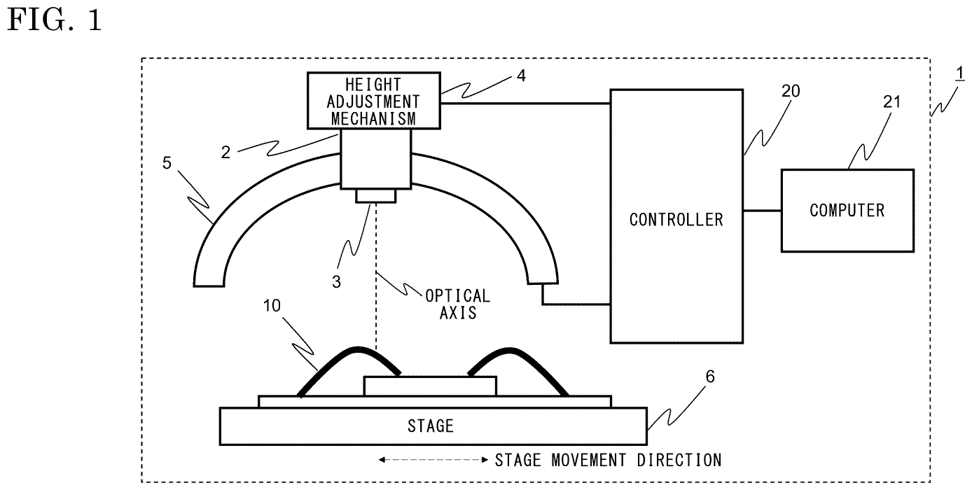

FIG. 1 shows the configuration of a shape inspection apparatus 1 for an inspection-target object according to embodiment 1. Here, a typical example of the inspection-target object is a bonding wire. The shape inspection apparatus 1 for the inspection-target object, which is an apparatus capable of inspecting the shape of the inspection-target object three-dimensionally includes: a camera 2; a lens 3 mounted to the camera 2; a height adjustment mechanism 4 (hereinafter, simply referred to as adjustment mechanism) for adjusting the distance between the camera 2 and a bonding wire 10; an illumination device 5 (in FIG. 1, the shape thereof is a dome shape) capable of controlling an emission angle of illumination light; a stage 6 on which the inspection-target object is placed and which moves the inspection-target object in a direction (in FIG. 1, a left-right direction indicated by a dotted-line arrow) perpendicular to the optical axis of the lens; a controller 20 which controls operation of the adjustment mechanism 4 and controls position change operation for the illumination device 5 (including change operation for an angular position described later in detail), intensity change operation for a light source of the illumination device 5 including light-up operation, change operation of a spectrum distribution, and an operation for causing the camera 2 to take an image of the inspection-target object; and a computer 21 which outputs a command signal for controlling the controller 20, calculates and recognizes the shape of the bonding wire 10 which is the inspection-target object from an image taken by the camera 2 and acquired via the controller 20 from the camera 2, and determines whether the inspection-target object is a proper product or a defective product.

Here, the bonding wire shape inspection apparatus 1 according to the present embodiment 1 is characterized by being capable of measuring the shape of a wire three-dimensionally at high speed, using a camera capable of recognizing a two-dimensional image, at lower cost, without using an expensive camera such as a stereo camera.

Here, as the camera 2, a commercial industrial camera is used, and the camera 2 is selected in accordance with various conditions such as a wire diameter of the bonding wire 10, a required pixel resolution, and a frame rate.

The lens 3 is selected in accordance with various conditions such as a wire diameter of the bonding wire 10, a required pixel resolution, or the field of view. For example, in a case where a plurality of bonding wires 10 which are inspection-target objects are present in the same field of view, if a normal lens is used, measurement error arises at, in particular, an end of the field of view in relation with the angle of view. Therefore, in a case where a plurality of bonding wires 10 which are inspection-target objects are present in the same field of view, a telecentric lens is used.

The height adjustment mechanism 4 is used for adjusting the distance between the camera 2 and the bonding wire 10 so as to take an image in focus. The height adjustment mechanism 4 may be provided on the stage 6 side, instead of on the camera side. The height adjustment mechanism 4 is needed in a case where the height of the wire cannot be covered within the depth of field of the camera 2 and the lens 3.

The illumination device 5 is capable of emitting illumination light from a desired angle. For example, the illumination device 5 has a dome shape, includes a plurality of light emitting elements, and is capable of controlling lighting-up and extinction of each light emitting element. Without limitation thereto, the illumination device 5 may include a movable mechanism and allow the position and the angle of the illumination device 5 to be controlled.

In the configuration not having the above movable mechanism, for a bonding wire present on the same plane, a plurality of images thereof can be taken while the emission angle of the illumination device is changed, whereby the three-dimensional shape of the bonding wire can be measured. Thus, high-speed inspection can be performed. This configuration can be realized at low cost.

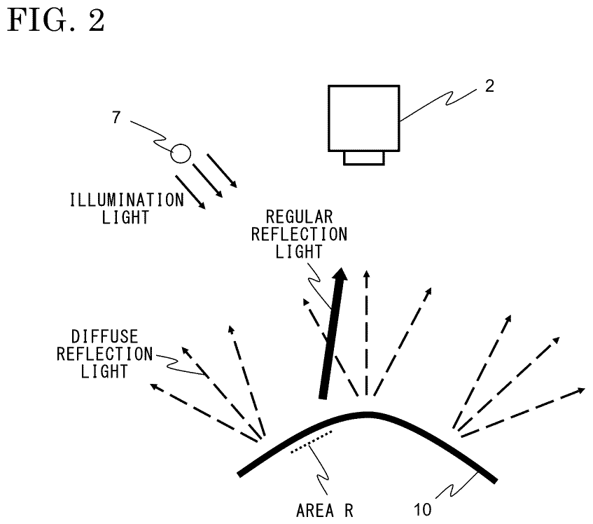

Next, a method for determining whether or not the shape of the bonding wire is proper by the bonding wire shape inspection apparatus 1 shown in FIG. 1 will be sequentially described below. First, with reference to FIG. 2, the illumination device and the camera which are basic components of this inspection apparatus will be described, focusing on the functions thereof.

FIG. 2 shows a state of reflection light reflected from the bonding wire 10 in a case where illumination light is emitted to the bonding wire 10 from a light source 7 which is an example of the illumination device 5.

In FIG. 2, the reflection light reflected from the bonding wire 10 includes two kinds of reflection light, i.e., regular reflection light which is reflection light from an area A which can be seen brightly from the camera 2 and diffuse reflection light which is reflection light from an area other than the area A, which can be hardly seen from the camera 2.

That is, in general, when illumination light from a light source hits on an object, regular reflection light and diffuse reflection light emerge. In this case, if the object is metal, the regular reflection light is strong and the diffuse reflection light is weak. Since the bonding wire is metal, when illumination light hits on the bonding wire, regular reflection light is stronger than diffuse reflection light.

In the present embodiment 1, when illumination light is emitted to the bonding wire 10, the entire bonding wire uniformly shines by diffuse reflection light (see broken-line arrows in FIG. 2).

Meanwhile, on the bonding wire, from an area R (see a part indicated by a dotted line in FIG. 2) having a specific angle with respect to the illumination light, regular reflection light goes to the camera 2 (see a thick solid-line arrow in FIG. 2). Thus, the area R appears brighter than the area other than the area R on the bonding wire.

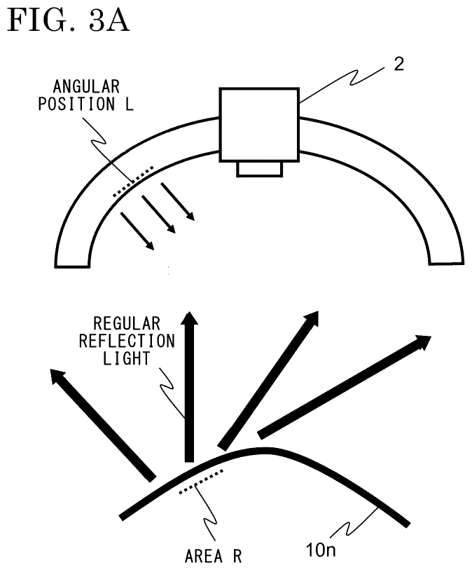

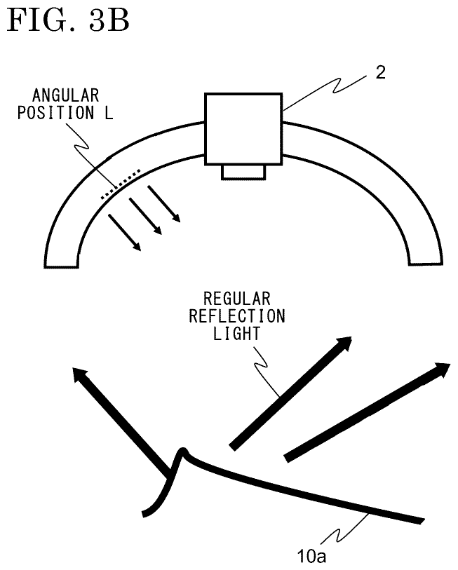

Next, in a case where the configurations of the illumination device (light source) and the camera described above are applied, the outline of a method for determining whether or not the three-dimensional shape of a bonding wire is proper will be described, using a typical shape of a bonding wire, with reference to FIG. 3A and FIG. 3B.

Here, FIG. 3A conceptually shows paths of regular reflection light in a case of emitting illumination light to a bonding wire 10n having a normal shape, and FIG. 3B conceptually shows paths of regular reflection light in a case of emitting illumination light to a bonding wire 10a having a defective shape. In these drawings, the angular position of the illumination device is the same between the drawings, and is an angular position L.

From FIG. 3A, it is found that, in a case of emitting illumination light to the bonding wire 10n having a normal shape, regular reflection light from the area R which appears bright reaches the camera 2. On the other hand, from FIG. 3B, it is found that, in a case of emitting illumination light to the bonding wire 10a having a defective shape, regular reflection light does not reach the camera 2.

That is, it is found that the bonding wire shape inspection apparatus 1 shown in FIG. 1 can determine whether or not the shape of a bonding wire is proper.

Hereinafter, a specific method for determining whether or not the three-dimensional shape of a bonding wire is proper will be described more specifically. In particular, a measurement method in which measurement based on an image and the like are applied will be described using a flowchart.

Although not described in detail, the measurement method specifically described below is applicable also to a case of detecting bending of a bonding wire, contact between crossing bonding wires, and contact between a wire and a structure.

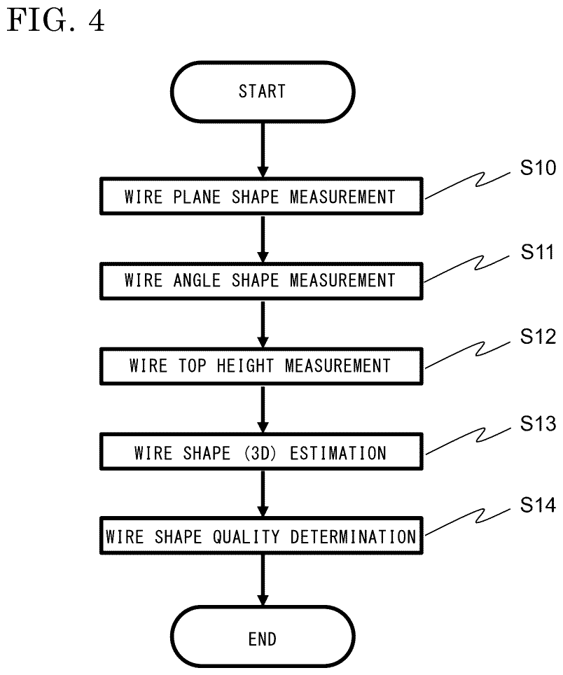

FIG. 4 is a flowchart showing the outline of a procedure of a measurement method for performing determination three-dimensionally as to whether or not the bonding wire shape is proper.

First, in step S10, plane shape measurement for a bonding wire is performed. This measurement is performed as follows. A plane perpendicular to the optical axis of the camera 2 is defined as P, and the shape of a bonding wire is projected on a (x, y) coordinate system which is a coordinate system on the plane P, so that a plurality of points on the bonding wire are projected on the plane P. Then, a plurality of sets of (x, y) coordinates corresponding to the plurality of points are measured. More detailed description of the measurement method will be given later.

Next, in step S11, angle shape measurement for the bonding wire is performed. Here, an angle θ thereof (hereinafter, referred to as angle shape θ) is defined as an angle at which the bonding wire as an inspection-target object is placed with respect to the plane P. More detailed description of the angle shape measurement will be given later.

Next, in step S12, top height measurement for the bonding wire is performed. Here, a top height zt refers to a height of the top of the bonding wire 10, i.e., a point at which the height in a z direction is greatest. More detailed description for the top height measurement will be given later.

In the top height measurement for the bonding wire, the top of the bonding wire 10, i.e., a point at which the height in the z direction is greatest, is measured on the basis of focus information on the bonding wire (here, this information is obtained by determining an image that is in focus the best from a difference from adjacent pixels and then using this as a point at which the height in the z direction is greatest, for example). Thus, it is possible to more accurately measure the three-dimensional shape of the bonding wire 10.

Measurements for three items described above, i.e., the plane shape measurement, the angle shape measurement, and the top height measurement, are performed on a plurality of points of the bonding wire 10, and on the basis of three kinds of data measured as described above at the respective points, the three-dimensional shape of the bonding wire is estimated in step S13. The estimated shape is compared with the values of a plurality of points in master data (three-dimensional shape data as a reference) of a bonding wire calculated through measurement in advance, to determine whether or not the three-dimensional shape of the bonding wire is proper (step S14).

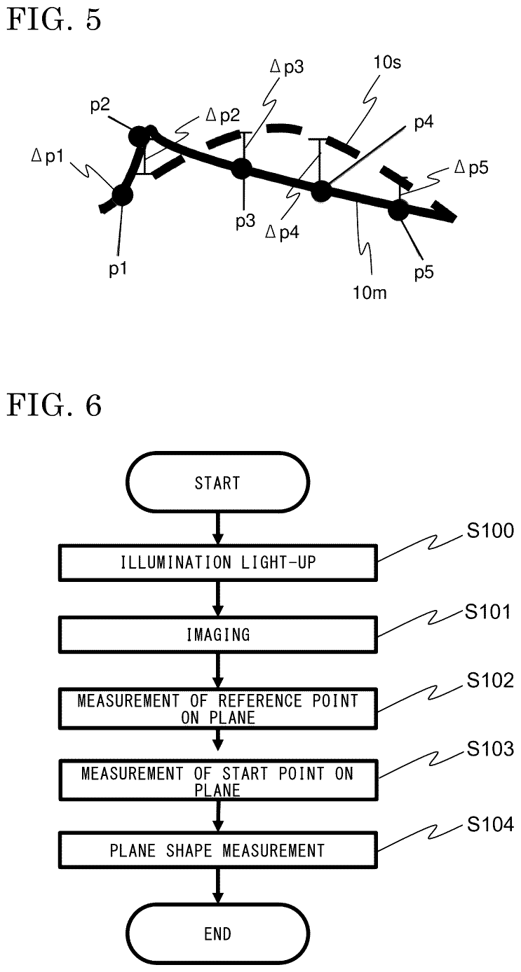

Next, a specific example of a method for comparison with the master data will be described with reference to FIG. 5.

In FIG. 5, a dotted line represents the shape of a bonding wire 10s as a reference two dimensionally. In addition, a solid line represents a measured shape of a bonding wire 10m two dimensionally.

For five points on the bonding wire 10m represented by the solid line, data obtained through measurement are defined as p1=p((x1, y1), z1, θ1), p2=p((x2, y2), z2, θ2), p3=p((x3, y3), z3, θ3), p4=p((x4, y4), z4, θ4), and p5=p((x5, y5), z5, θ5), in order from the left.

Here, (xm, ym) (here, m is an integer from 1 to 5) is data obtained through the plane shape measurement, θm (here, m is an integer from 1 to 5) is data obtained through the angle shape measurement, and zm (here, m is an integer from 1 to 5) is data obtained through the top height measurement.

Between data for five points on the bonding wire 10m and data for five points (these points are denoted by p₀1, p₀2, . . . , p₀5) on the bonding wire 10s as a reference that correspond to measurement positions for the above five points, differences are calculated (these differences are respectively denoted by Δp1, Δp2, Δp3, Δp4, and Δp5, as shown in FIG. 5) (for example, Δp1=|p1−p₀1|). Then, values of (Δpm)² (here, m is an integer from 1 to 5) at m=1 to 5 are calculated and summed, and the square root of the sum is calculated. Subsequently, the square root is compared with a predetermined threshold ε in terms of the magnitude relationship.

In this case, if the square root is not greater than the threshold ε, it is determined that the three-dimensional shape of the bonding wire is proper. If the square root is greater than the threshold ε, it is determined that the three-dimensional shape of the bonding wire is defective. The above process is a specific example of step S14.

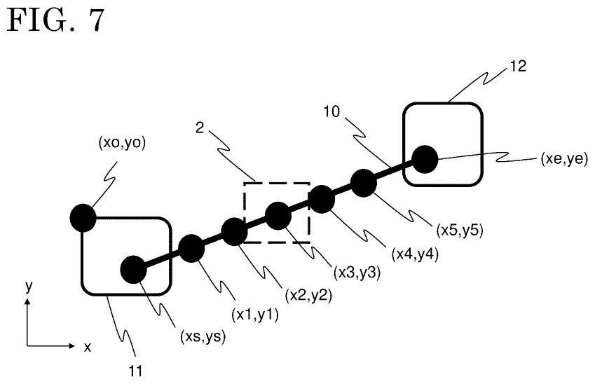

Next, with reference to FIG. 6 and FIG. 7, the details of the wire plane shape measurement in step S10 will be described. Here, FIG. 6 is a flowchart illustrating the details of the wire plane shape measurement in step S10, and FIG. 7 shows collection of coordinate points, on the (x, y) plane, of an image of the bonding wire 10 taken by the camera 2.

In the flowchart shown in FIG. 6, in illumination light-up in step S100, the computer 21 causes the illumination device 5 to light up via the controller 20. In imaging in the next step S101, the computer 21 issues an imaging command to the camera 2, to take an image of the bonding wire 10. Then, from the taken image, an image of the bonding wire 10 is identified, and the position coordinates of a plurality of points of the image on the (x, y) plane are measured.

In the reference point measurement on the plane in the next step S102, a corner of a structure present near the bonding wire 10 which is an inspection-target object, e.g., a bonding pad 11 located on the left side in the drawing, is defined as a reference point (xo, yo), and the position coordinates of the reference point on the (x, y) plane are measured.

Here, a state in which the bonding pad 11 is present near the bonding wire 10 refers to a positional relationship between an end point of the bonding wire 10 and the bonding pad 11 in a case where the end point of the bonding wire 10 is connected to the bonding pad 11.

In start point measurement on the plane in the next step S103, using coordinates relative to the reference point, whether or not a start point (xs, ys) of the bonding wire 10 which is an inspection-target object is present at a normal position is determined. Whether or not the start point (xs, ys) of the bonding wire 10 is present at a normal position is determined by a threshold th₁ and the following Formula (1).

$$[ Mathematical 1 ]$$

$$\sqrt{{( {x}_{s} - {x}_{o} )}^{2} + {( {y}_{s} - {y}_{o} )}^{2}} < {th}_{1} \qquad ( 1 )$$

In the above description, the position (xs, ys) of an end of the bonding wire 10 is used as a start point. However, a point other than the position of an end of the wire, e.g., the point (x1, y1), may be used as a start point.

The normal position refers to such a position that the end point (xs, ys) of the bonding wire 10 is located in the bonding pad 11 indicated by a rectangular frame in FIG. 7, for example. The above step S103 is a step needed for identifying whether or not an object in an image is a bonding wire which is an inspection-target object.

In the plane shape measurement in step S104, the wire shape (sets of plane coordinates (x, y) of the wire) is sequentially measured at a plurality of points while tracing along the bonding wire 10 which is the inspection-target object from the start point (xs, ys) to another end point (xe, ye) of the bonding wire 10. For example, in FIG. 7, points (x1, y1), (x2, y2), . . . (x5, y5) are measured. Then, as shown in FIG. 7, the shape of the bonding wire may be recorded as a set of the start point (xs, ys), intermediate points (x1, y1), (x2, y2), . . . , (xn, yn), and the end point (xe, ye), or contour information on the wire may be recorded as it is. Here, the number and the interval of the intermediate points are determined in consideration of the length of the bonding wire 10, the pixel resolution of the camera 2, and the like.

The point (xe, ye) is another end point of the bonding wire 10 that is different from the start point (xs, ys) on the bonding pad 11 and is located in the bonding pad 12. In FIG. 7, arrows x and y at the lower left indicate directions in a plane coordinate system (x, y).

In a case where a plurality of wires are present in the image and the start point (xs, ys) of the bonding wire 10 which is the inspection-target object is not located at a normal position, it is impossible to identify which wire is the bonding wire 10 which is the inspection-target object.

In the case where the bonding wire 10 which is the inspection-target object cannot be identified as described above, a step (step S104) subsequent to step S103 may not be performed for the wire, or the subsequent step may be successively performed for a wire that is likely to be the bonding wire 10 which is the inspection-target object.

For example, a wire that is likely to be the bonding wire 10 which is the inspection-target object is determined by the following Formula (2), using a threshold th₂. Among wires that are likely to be the bonding wire 10 which is the inspection-target object, a wire that satisfies Formula (2) and for which the left-hand side of Formula (2) is smallest is subjected to the subsequent step.

$$[ Mathematical 2 ]$$

$$\sqrt{{( {x}_{s} - {x}_{o} )}^{2} + {( {y}_{s} - {y}_{o} )}^{2}} < {th}_{2} \qquad ( 2 )$$

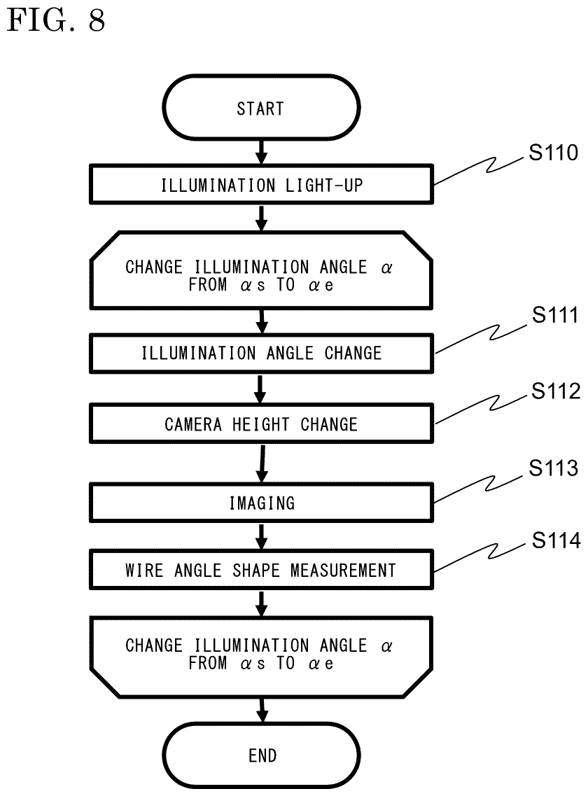

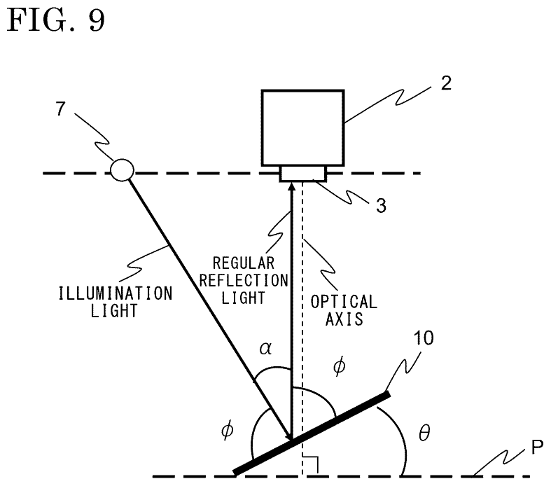

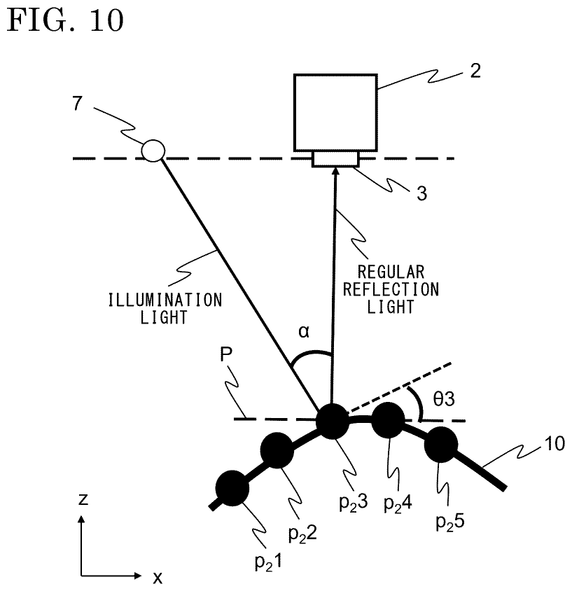

Next, the details of the wire angle measurement method (step S11 in FIG. 4) will be described below with reference to FIG. 8, FIG. 9, and FIG. 10. Here, an angle of the bonding wire 10 with respect to a predetermined plane (here, a plane perpendicular to the optical axis of the lens 3) is measured as a depth-direction angle of the bonding wire 10 when viewed from the camera 2.

First, FIG. 8 will be described. FIG. 8 illustrates the principle of the aforementioned wire angle measurement method.

In FIG. 8, illumination light from the light source 7 is regularly reflected by the bonding wire 10 and then is captured by the camera 2, whereby the depth-direction angle of the bonding wire 10 with respect to the camera 2 can be measured.

As shown in FIG. 8, it is assumed that the bonding wire is placed at the angle θ with respect to a plane P perpendicular to the optical axis of the lens 3 attached to the camera 2 (this axis can also be considered the optical axis of the camera 2 and thus, hereinafter, may be referred to as the optical axis of the camera 2). In this case, an incidence angle and a reflection angle of illumination light with respect to the bonding wire are denoted by φ, and an angle formed between the incidence angle and the reflection angle is denoted by α. The angle α is an angle indicating the placement position of the light source with respect to the optical axis of the camera 2, as shown in the drawing. Therefore, hereinafter, a may be referred to as an angular position of the illumination device.

In a case as shown in FIG. 8, i.e., in a case where regular reflection light based on illumination light from the light source enters the camera placed directly upward of the bonding wire, the angle shape θ of the bonding wire and φ which is the incidence angle and the reflection angle of the illumination light have a relationship of θ+φ=90°. Thus, it is found that a relationship of α=2θ is consequently satisfied in this case.

From above, it is found that, in a case where a part of the bonding wire shines strongly when illumination light is regularly reflected, the angle θ indicating the shape of the part of the bonding wire can be measured from the angular position α with respect to the lens optical axis of the illumination device (light source).

Next, a method for performing the wire angle shape measurement at a plurality of points on the bonding wire 10 using the wire angle measurement method based on the principle described regarding the bonding wire 10 will be described. That is, using the wire angle shape measurement method (measurement for the angle θ in FIG. 8) described in step S11, the angle θ at each measurement point of the bonding wire 10 is measured while the emission angle of the illumination device with respect to the bonding wire 10 is changed. Hereinafter, with reference to FIG. 9 which shows a flowchart of this method, the details of the wire angle shape measurement at each measurement point of the bonding wire 10 will be described.

FIG. 9 is a flowchart showing the details of the wire angle shape measurement in step S11 (see FIG. 4). In illumination light-up in step S110, the computer 21 causes the illumination device 5 to light up via the controller 20. Next, in illumination angle change in the next step S111, the angle α of illumination light with respect to the optical axis of the camera is changed in a range of αs≤α≤αe. Here, αs and αe may be determined in accordance with angles (a range of change in θ) that the bonding wire 10 can have. The change amount when the angle is changed from αs to αe is determined in accordance with required measurement accuracy.

In a case where regular reflection light from a bonding wire (in this case, φ=0° and θ=90°) perpendicular to the above plane P is to be captured by the camera, illumination light is to be emitted from a position at α=180°, i.e., a position directly downward of the camera 2. Therefore, in this case, the angle of the bonding wire cannot be measured due to physical constraints.

In camera height change in the next step S112, in accordance with the angle of the illumination device, the height of the camera is adjusted so that the bonding wire is in focus. In this case, since the shape of the bonding wire 10 is the same as long as the bonding wire 10 is a proper product, it is already known which part of the wire emits regular reflection light when illumination light is emitted at the angle θ to the bonding wire 10. Accordingly, the height of the camera is adjusted to such a position that the part of the bonding wire 10 that will appear bright by regular reflection light entering the camera is in focus.

In imaging in the next step S113, the computer 21 issues an imaging command to the camera 2 to take an image including the wire.

In the next step S114, the angle shape θ at each of a plurality of points of the bonding wire is sequentially measured from the taken image.

In this regard, with reference to FIG. 10, a case where illumination light is emitted at the angle α to the bonding wire 10 will be described below. The values measured in the wire angle measurement at the measurement points (xm, ym) (here, m is an integer from 1 to 5) measured in the wire plane shape measurement in step S10 are denoted by θm (m is an integer from 1 to 5). In this case, each measurement point p₂m (here, m is an integer from 1 to 5) shown in FIG. 10 can be represented as p₂m=p₂ ((xm, ym), θm) (m is an integer from 1 to 5). Then, it is assumed that regular reflection light from a part corresponding to plane coordinates (xm, ym) of the measurement point p₂m enters the camera 2 and an image appearing bright has been successfully taken.

In this case, an angle θ3 of the bonding wire 10 at a measurement point p₂3 can be calculated as θ3=0.5α from the angle α of the illumination light with respect to the optical axis. In FIG. 10, arrows (a pair of arrows) shown at the lower left indicate directions in a coordinate system (x, z) in this drawing. Here, x indicates an x direction in the plane coordinate system, and z indicates the height direction of the bonding wire 10 (the depth direction as seen from the camera 2, which also corresponds to the optical-axis direction) (the same applies in the following drawings).

As described above, through steps S111 to S114, images of the wire are taken while the emission angle of illumination light is changed in the above range of αs≤α≤αe, and the angle shape θ is measured for each case.

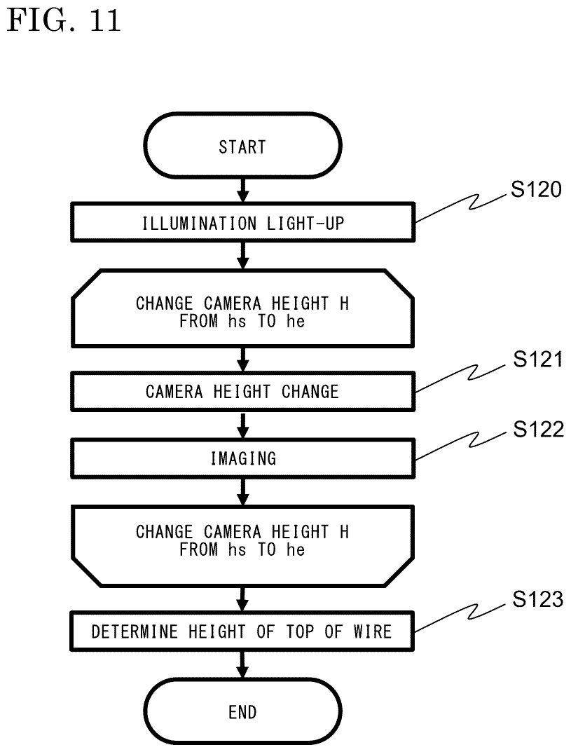

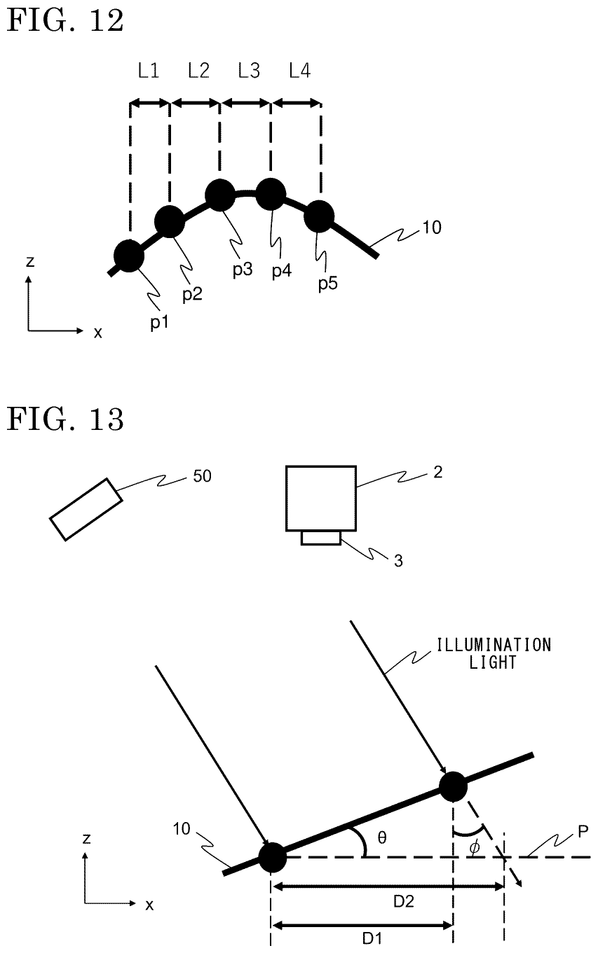

Next, the details of a method for the wire top height measurement (step S12 in FIG. 4) will be described with reference to FIG. 11 and FIG. 12. In the wire top height measurement for measuring the height of the top of the bonding wire in step S12, the top of the bonding wire 10, i.e., the point at which the height in the z direction is greatest, is measured. Thus, the three-dimensional shape of the bonding wire 10 can be measured more accurately.

FIG. 11 is a flowchart showing the details of the wire top height measurement for the bonding wire 10.

First, in illumination light-up in step S120, the illumination device for taking an image of the top of the bonding wire 10 is lit up. The illumination light may be emitted at an angle α=90° so that the top of the bonding wire 10 strongly reflects the light, or may be emitted at such an angle that the top part will uniformly shine by diffuse reflection light.

In camera height change in the next step S121, the camera position is adjusted to such a height that the top of the bonding wire 10 is in focus. The position of the top of the bonding wire 10 as seen on the (x, y) coordinate plane is assumed to be a position at which θ measured at the measurement point in the wire angle shape measurement in step S11 is 0 or a position at which two adjacent measurement points satisfy θa<0<θb (θa and θb are measurement values of angles at the two measurement points).

Here, an upper limit hs and a lower limit he of the camera height are determined as appropriate in accordance with a range in which the top of the bonding wire 10 can exist. The change amount when the height is changed from hs to he (the change amount per one position change) is determined in accordance with required measurement accuracy.

In imaging in the next step S122, the computer 21 issues an imaging command to the camera 2 to take an image of the bonding wire.

Through repetition of the above steps S121 to S122, images of the top of the bonding wire 10 are taken from different heights, to obtain collection of taken images. In the next step S123, a top height zt of the bonding wire 10 is determined from the taken images.

Here, it is assumed that, through repetition of steps S121 and S122, a plurality of sets of taken images I and camera heights h, i.e., (I1, h1), (I2, h2), . . . , (In, hn), have been obtained. Then, from this collection, an image in which the top of the bonding wire 10 is in focus the best is determined.

In this determination, image processing (e.g., convolution integral) is performed with the image I and, for example, a Laplacian filter F for eight neighbors, which is one of image processing filters for the image I. Here, if elements of the image I and the Laplacian filter F are represented as shown by the following Formula (3), a result of image processing is represented as shown by Formula (4), using elements G of convolution integral, for example.

$$[ Mathematical 3 ]$$

$$I = [ \begin{matrix}{i}_{0 , 0} & ⋯ & {i}_{x , 0} \\ ⋮ & ⋱ & ⋮ \\ {i}_{0 , y} & ⋯ & {i}_{x , y}\end{matrix} ] , F = [ \begin{matrix}{f}_{- i , - j} & ⋯ & {f}_{i , - j} \\ ⋮ & {f}_{0 , 0} & ⋮ \\ {f}_{- i , j} & ⋯ & {f}_{i , j}\end{matrix} ] \qquad ( 3 )$$

$$[ Mathematical 4 ]$$

$$G = I = [ \begin{matrix}{\sum }_{p = - i}^{i} {\sum }_{q = - j}^{j} {I}_{( 0 + p , 0 + q )} \cdot {F}_{( p , q )} & ⋯ & {\sum }_{p = - i}^{i} {\sum }_{q = - j}^{j} {I}_{( x + p , 0 + q )} \cdot {F}_{( p , q )} \\ ⋮ & ⋱ & ⋮ \\ {\sum }_{p = - i}^{i} {\sum }_{q = - j}^{j} {I}_{( 0 + p , y + q )} \cdot {F}_{( p , q )} & ⋯ & {\sum }_{p = - i}^{i} {\sum }_{q = - j}^{j} {I}_{( x + p , y + q )} \cdot {F}_{( p , q )}\end{matrix} ] \qquad ( 4 )$$

That is, image processing represented by the above elements of convolution integral is performed, and on the basis of the obtained result, determination for the image is performed.

Here, in the Laplacian filter F, through second-order differentiation, a part where a difference between pixel values of adjacent pixels is great in an image is emphasized in general (see, for example, Patent Document 2), so that a brightness value of a bonding wire in an image q becomes greater when the image comes closer into an in-focus state. Then, from the image q, a part where a point estimated to be the top of the bonding wire appears is extracted, and a sum S of pixel values in the extracted area is calculated. The top height zt of the bonding wire 10 can be measured from the focal length of the lens 3 and the camera height h when the sum S of the pixel values is maximized.

The wire plane shape measurement in step S10, the wire angle shape measurement in step S11, and the wire top height measurement in step S12 may be performed at the same time. For example, using one image taken by emitting illumination light at a certain angle α to an inspection-target object, the wire plane shape measurement, the wire angle shape measurement, and the wire top height measurement may be performed at the same time.

In wire shape estimation in the next step S13, wire heights at other measurement points are estimated on the basis of the top height zt of the bonding wire 10 measured in the wire top height measurement in step S12 and the angle θ at each measurement point of the bonding wire 10 measured in the wire angle shape measurement in step S11.

In FIG. 12, the measured top height zt of the bonding wire 10 corresponds to the measurement point p3=p((x3, y3), z3, θ3) (here, z3=zt).

The same applies to the other measurement points p1, p2, p4, p5 (e.g., p2=p((x2, y2), z2, θ2)). Here, on the (x, y) coordinate plane, a relative distance Lxy between the measurement point (x3, y3) (here, z=z3=zt, θ=θ3) and the measurement point (x2, y2) (here, z=z2, θ=θ2) in the plane coordinate system can be represented by the following Formula (5).

$$[ Mathematical 5 ]$$

$$Lxy = {\{ {( x 3 - x 2 )}^{2} + {( y 3 - y 2 )}^{2} \}}^{1 / 2} \qquad ( 5 )$$

At this time, the bonding wire height z2 at the adjacent measurement point can be represented by the following Formula (6), using Lxy and θ3 described above.

$$[ Mathematical 6 ]$$

$$z 2 = Lxy tan ( θ3 ) \qquad ( 6 )$$

Using the above, bonding wire heights can be estimated for all the measurement points. Here, L1, L2, L3, and L4 are the interval between p1 and p2, the interval between p2 and p3, the interval between p3 and p4, and the interval between p4 and p5 in the (x, y) coordinate system.

In quality determination for the bonding wire shape in step S14 (see FIG. 4), whether or not the wire shape is proper is determined on the basis of estimation data of the wire shape measured in the previous step. Here, as described above, the determination is performed through comparison between estimation data of the measured wire shape and wire shape data of a proper product (having a normal shape). Another determination condition may be added as necessary. For example, in a case where there are wires crossing each other, if a difference between wire heights z at the crossing part is smaller than a certain threshold, it may be determined that the product is defective because the wires are likely to be in contact with each other.

In a case where a wire might contact with a structure, position data of the structure and wire shape data may be compared, and through comparison between a threshold and the difference of the above two data, whether or not the wire and the structure are in contact with each other may be determined.

### Embodiment 2

An inspection apparatus for an inspection-target object according to embodiment 2 includes, in addition to the illumination device 5, an illumination device which projects a grid formed of parallel lines at equal intervals, i.e., a grid projection illumination device 50.

It is possible to perform inspection at higher speed by performing the wire angle shape measurement in step S11, using the grid projection illumination device 50.

FIG. 13 shows a method for measuring the wire angle shape, using the grid projection illumination device 50. To the bonding wire 10 having the angle shape θ, illumination light is emitted from the grid projection illumination device 50 at an emission angle φ with respect to the optical axis, and an image in which a grid pattern is projected on the bonding wire 10 is taken by the camera 2. Then, it is assumed that the grid interval has been confirmed to be L1.

At this time, the emission angle φ can be represented by the following Formula (7), using the angle shape θ of the bonding wire 10, an interval D1 (interval on plane P) between two adjacent grid lines, and an interval D2 of a grid that appears when illumination light is emitted in a direction perpendicular to the reference plane P corresponding to θ=0.

$$[ Mathematical 7 ]$$

$$ϕ = arctan ( \vert D 2 - D 1 \vert / D 1 tan θ ) \qquad ( 7 )$$

The angle θ of the bonding wire 10 can be measured from the interval L1 of the grid pattern projected on the bonding wire 10, using the above Formula (7). Through this measurement method, it is possible to measure the angle θ of the bonding wire 10 more accurately.

The matters other than the wire angle shape measurement in step S11 are the same as in embodiment 1, and therefore the detailed description thereof is omitted here.

### Embodiment 3

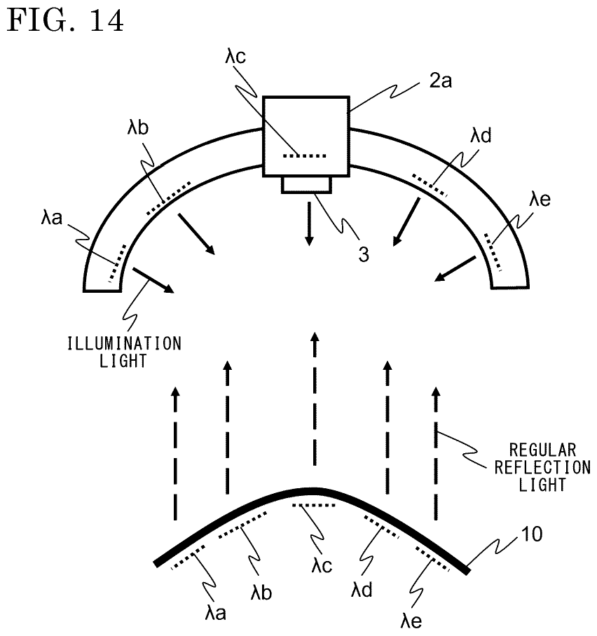

An inspection apparatus according to embodiment 3 has, in addition to the configuration of the inspection apparatus according to embodiment 1 (the configuration in which the illumination device 5 can emit illumination light from a desired angle), a configuration in which illumination light rays having spectrum distributions and having predetermined center wavelengths or peak wavelengths (illumination light rays having predetermined spectrum distributions) can be emitted from different angles at the same time (see FIG. 14).

With this configuration, for example, illumination light having a center wavelength A1 is emitted from an angle α1, and at the same time, illumination light having a center wavelength λ2 is emitted from an angle α2. Then, these illumination light rays are captured by the camera 2 (not shown). Thus, the number of times of imaging in the wire angle shape measurement in step S11 can be decreased, so that it becomes possible to perform inspection at higher speed.

Further, a hyperspectral camera 2a may be used and illumination light rays having different center wavelengths or peak wavelengths (in FIG. 14, having spectrum-distributed characteristics with five different center wavelengths or peak wavelengths of λa, λb, λc, λd, and λe), i.e., illumination light rays having different spectrum distributions, may be emitted from more angles at the same time. Also in this case, the number of times of imaging can be significantly decreased (see FIG. 14).

In FIG. 14, solid-line arrows indicate illumination light emitted from a dome-shaped illumination device to the bonding wire 10, and dotted-line arrows indicate regular reflection light reflected from the bonding wire 10 toward the hyperspectral camera 2a on the basis of the illumination light. The matters other than the wire angle shape measurement in step S11 are the same as in embodiment 1.

### Embodiment 4

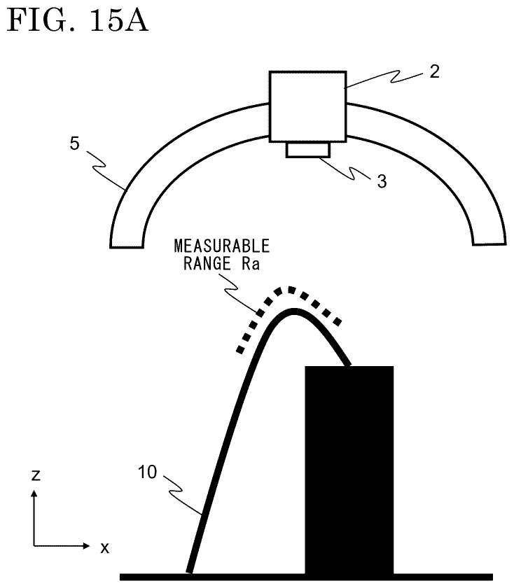

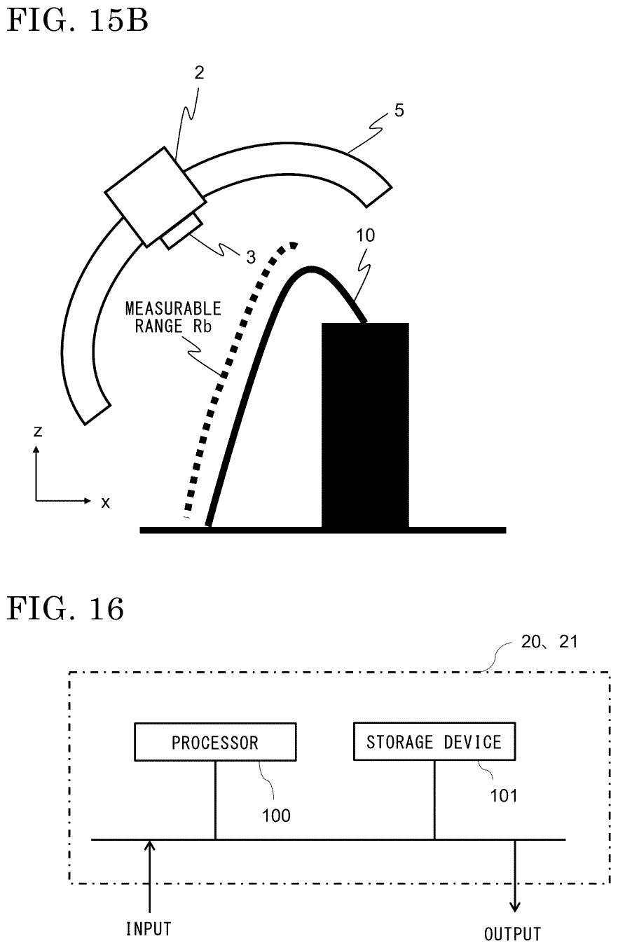

In the inspection apparatus according to embodiment 1, a movable mechanism may be provided to the camera 2 and the illumination device 5 or to the stage 6, so that the positional relationship between the bonding wire 10, and the camera 2 and the illumination device 5, can be freely changed (see, for example, FIG. 15A and FIG. 15B). Such a configuration corresponds to an inspection apparatus according to the present embodiment 4.

With the above configuration, it is possible to measure also the three-dimensional shape of the bonding wire 10 having a complicated shape, in the wire angle shape measurement in step S11. For example, in a case where the bonding wire 10 is present between structural parts having a height difference as shown in FIG. 15, if an image is taken from directly above in inspection, it is difficult to perform angle measurement for a wire part that is almost vertical, and therefore only a part that is very close to the top of the bonding wire can be measured (see measurable range Ra in FIG. 15A).

However, by adjusting the positional relationship between the bonding wire 10, and the camera 2 and the illumination device 5, it becomes possible to perform angle measurement also for a part (see measurable range Ra in FIG. 15B) for which measurement could not be performed from directly above. Thus, even in a case of measuring a bonding wire having a complicated shape, it is possible to perform accurate angle measurement.

The matters other than the wire angle shape measurement in step S11 are the same as in embodiment 1, and therefore the description thereof is omitted here.

The controller 20 described above, as with the computer 21, is composed of a processor 100 and a storage device 101 as shown in a hardware example in FIG. 16. The storage device 101 is provided with a volatile storage device such as a random access memory and a nonvolatile auxiliary storage device such as a flash memory (not shown). Instead of the flash memory, an auxiliary storage device of a hard disk may be provided. The processor 100 may execute a program inputted from the storage device 101. In this case, the program is inputted from the auxiliary storage device to the processor 100 via the volatile storage device. The processor 100 may output data such as a calculation result to the volatile storage device of the storage device 101, or may store such data into the auxiliary storage device via the volatile storage device.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment. For example, in three-dimensional measurement for an inspection-target object, a case where the number of measurement points is five has been shown. However, the number of measurement points, the measurement range, and the like may be changed in accordance with a measurement target or a measurement purpose. Specifically, for example, in a case of measuring presence/absence of contact between crossing wires, the measurement range may be limited to a range where contact can occur, and measurement may be performed only in the limited range. Thus, the measurement time can be shortened.

### DESCRIPTION OF THE REFERENCE CHARACTERS

1 shape inspection apparatus for inspection-target object
2 camera
2a hyperspectral camera
3 lens
4 height adjustment mechanism (adjustment mechanism)
5 illumination device
6 stage
7 light source
10, 10a, 10m, 10n, 10s bonding wire
11, 12 bonding pad
20 controller
21 computer
50 grid projection illumination device
100 processor
101 storage device

1. (canceled)

2. (canceled)

3. (canceled)

4. (canceled)

5. A shape inspection method for an inspection-target object, using a shape inspection apparatus for the inspection-target object, the shape inspection apparatus comprising:
a camera which is provided movably relative to the inspection-target object and takes an image of the inspection-target object;
an adjustment mechanism for adjusting a distance between the camera and the inspection-target object;
an illumination device which has a light source for emitting light to the inspection-target object and is capable of changing a position of the light source;
a controller which controls operation of the adjustment mechanism and controls position change operation of the light source of the illumination device, light-up operation thereof, change operation of a spectrum distribution thereof, and operation for the camera to take an image of the inspection-target object; and
a computer which outputs an operation command to the controller for commanding operation of changing positions of the camera and the light source relative to the inspection-target object, light-up operation of the light source, operation of changing the spectrum distribution of the light source, and operation for the camera to take an image of the inspection-target object, and controls the controller, comprising at least one processor and at least one memory, wherein
while the position of the camera is moved and an irradiation position of light from the light source to the inspection-target object is changed, an image of the inspection-target object is taken, and on the basis of the taken image, a shape of the inspection-target object is estimated and compared with a shape of an inspection-target object as a reference measured in advance, by the computer, to determine a three-dimensional shape of the inspection-target object, and
in the shape inspection method,
with respect to the inspection-target object, while a position of the illumination device is changed, for each of the changed position, from a plane position of the inspection-target object when the inspection-target object is projected on a plane perpendicular to an optical axis of the camera, an angle shape of the inspection-target object calculated from an angular position of the illumination device when regular reflection light from the inspection-target object enters the camera, and a top height of the inspection-target object calculated from an image taken at an in-focus position when the camera is moved in an optical-axis direction of the camera relative to the inspection-target object, the three-dimensional shape of the inspection-target object is calculated, and a shape of the inspection-target object is determined.

6. A shape inspection method for an inspection-target object, using a shape inspection apparatus for the inspection-target object, the shape inspection apparatus comprising:
a camera which is provided movably relative to the inspection-target object and takes an image of the inspection-target object;
an adjustment mechanism for adjusting a distance between the camera and the inspection-target object;
a grid projection illumination device which has a light source for emitting light to the inspection-target object and is capable of changing a position of the light source, and which projects a grid formed of parallel lines at regular intervals;
a controller which controls operation of the adjustment mechanism and controls position change operation of the light source of the illumination device, light-up operation thereof, change operation of a spectrum distribution thereof, and operation for the camera to take an image of the inspection-target object; and
a computer which outputs an operation command for commanding operation of changing positions of the camera and the light source relative to the inspection-target object, light-up operation of the light source, operation of changing the spectrum distribution of the light source, and operation for the camera to take an image of the inspection-target object, and controls the controller, comprising at least one processor and at least one memory, wherein
while the position of the camera is moved and an irradiation position of light from the light source to the inspection-target object is changed, an image of the inspection-target object is taken, and on the basis of the taken image, a shape of the inspection-target object is estimated and compared with a shape of an inspection-target object as a reference measured in advance, by the computer, to determine a three-dimensional shape of the inspection-target object, and
in the shape inspection method,
on the basis of an angle shape of the inspection-target object and a grid interval measured by, with the camera, taking an image of a grid pattern projected on the inspection-target object, which is obtained when the inspection-target object is irradiated by the grid projection illumination device, the three-dimensional shape of the inspection-target object is measured and whether or not a shape of the inspection-target object is proper is determined.

7. The shape inspection method for the inspection-target object according to claim 1, using the shape inspection apparatus, wherein
the camera is a hyperspectral camera,
the illumination device has a plurality of light sources which emit light rays having different spectrum distributions from different angular positions to the inspection-target object,
the illumination device emits light rays from a plurality of angular positions to the inspection-target object at the same time, and
in the shape inspection method,
illumination light rays are emitted from a plurality of positions to the inspection-target object at the same time.

8. The shape inspection method for the inspection-target object according to claim 1, using the shape inspection apparatus, wherein
the inspection-target object is mounted on a movable stage, and
in the shape inspection method,
the inspection-target object is measured while a positional relationship between the inspection-target object, and the camera and the illumination device, is changed.
